(19) United States
(12) Patent Application Publication
(10) Pub. No.: US 2025/0264568 A1
(43) Pub. Date: Aug. 21, 2025

(54) SELF-CALIBRATING ELECTRICAL STANDARDS

(71) Applicant: GUILDLINE INSTRUMENTS LIMITED, Smiths Falls (CA)

(72) Inventor: Richard TIMMONS, Ottawa (CA)

(21) Appl. No.: 19/045,085

(22) Filed: Feb. 4, 2025

Related U.S. Application Data
(60) Provisional application No. 63/555,511, filed on Feb. 20, 2024.

(51) Int. Cl. G01R 35/00

(52) U.S. Cl. CPC G01R 35/007

(57) ABSTRACT

Within electrical test equipment systems comparator bridges are employed to provide the required dynamic range, accuracy, and flexibility. However, whilst bridge based measurement configurations remove many of the issues associated with making measurements at accuracies of sub-parts, a part, or few parts per million they still require, in many instances, that a null point be determined where the bridge is balanced. However, this becomes increasingly difficult within electrically noisy environments, with modern digital multimeters, and where the desired measurement point within the electrical system is physically difficult to access particularly when improved accuracy in calibration, standards, and measurements on circuits and components means measurement systems must operate at 50 parts per billion (ppb) and below. In order to address this, a null detector design is provided supporting operation within such electrically noisy environments with physical separation of the null detector measurement circuit from the electrical test equipment.

### CROSS-REFERENCE TO RELATED APPLICATIONS

This patent application claims the benefit of priority to U.S. Provisional Patent Application 63/555,511 filed Feb. 20, 2024; the entire contents of which are incorporated herein by reference.

### FIELD OF THE INVENTION

This invention relates generally to self-calibrating electrical standards for test in instruments exploiting null detection circuits for precision electrical measurements and precision transducers over current ranges from 1 mA or less to 20 kA or greater, voltage ranges of 1 V or less to 1000 kV or greater, resistance ranges from 1 μΩ or less to 10 PΩ or greater, and over frequency ranges from DC to hundreds of megahertz (MHz).

### BACKGROUND

Direct Current (DC) and Alternating Current (AC) electrical measurements are used in a wide variety of applications and may be performed for a variety of electrical quantities including voltage, current, capacitance, impedance, resistance etc. across a wide range of applications including those within industrial, scientific, military, medical and consumer fields for a wide variety of electrical and electronic devices directly or systems indirectly requiring precision electronic and electrical control. Accordingly, a wide range of electrical test and measurement systems are employed in the design, evaluation, maintenance, servicing and calibration of such electronic and electrical control circuits, systems and devices.

Within a variety of electrical measurement applications and electrical test equipment systems comparator bridges are employed to provide the required dynamic range, accuracy, and flexibility in order to mitigate many issues associated with achieving making measurements at accuracies of a part, or few parts per million, although they still require in many instances that a null point be determined, with a null detector, when the bridge is balanced. This becomes increasingly difficult within electrically noisy environments or where the desired measurement point within the electrical system is physically difficult to access. Accordingly, in order to address these issues and meet the continued drive for improved accuracy in calibration, standards, and measurements on circuits and components at the parts per billion (ppb) range inventors established null detector designs supporting operation within such electrically noisy environments with physical separation of the null detector measurement circuit from the electrical test equipment.

Within test and measurement equipment (TME) a voltage divider or resistive divider is commonly employed to produce output voltage(s) that are predetermined fractions of an input voltage or to provide a reference voltage for a TME system. For DC and low frequencies, a voltage divider may comprise only resistors but where a frequency response over a wide range is required (such as in an oscilloscope probe) the voltage divider may include additional capacitive elements to compensate for load capacitance. For TME accuracies in the ppb range the inventors have identified that even relatively simple passive elements such as voltage dividers cannot be used without calibration and that these calibrations may be required at frequencies substantially higher than the other elements within the TME. Accordingly, the inventors have established self-contained voltage dividers with internal calibration allowing the voltage divider to be calibrated periodically or for every measurement if necessary.

In order to address evolving TME requirements the inventors have extended their concepts for self-calibrating voltage dividers and provisioning of null detectors within either electrically noisy environments or limited physical access to provide systems that are automated and self-calibrating whilst providing multiple value electrical standards for one or more or voltage, resistance and current.

Other aspects and features of the present invention will become apparent to those ordinarily skilled in the art upon review of the following description of specific embodiments of the invention in conjunction with the accompanying figures.

It is an object of the present invention to mitigate limitations within the prior art relating to self-calibrating electrical standards for test in instruments exploiting null detection circuits for precision electrical measurements and precision transducers over current ranges from 1 mA or less to 20 kA or greater, voltage ranges of 1 V or less to 1000 kV or greater, resistance ranges from 1μΩ or less to 10 PΩ or greater, and over frequency ranges from DC to hundreds of MHz.

### SUMMARY

In accordance with an embodiment of the invention there is provided a device comprising:
an input port comprising an upper signal rail and a lower signal rail;
a first sample-and-hold (SH) circuit coupled to the upper signal rail having an output coupled to a first node of a bridge circuit comprising the first node, a second node, a third node and a fourth node;
a second SH circuit coupled to the lower signal rail having an output coupled to a second node of the bridge circuit;
the bridge circuit comprising a first resistor coupled to the first node and the second node, a second resistor coupled to first node and the third node, a third resistor coupled to the second node and the fourth node and a fourth resistor coupled to the third node and the fourth node;
a first output port coupled to the second node; and
a second output port coupled to the third node; wherein
the first resistor comprises a plurality of resistors in parallel of which a subset of the plurality of resistors are electrically tunable; and
adjustment of the subset of the plurality of resistors provides for adjustment of a voltage divider comprising the first resistor and third resistor.

In accordance with an embodiment of the invention there is provided a device comprising:
a first sample-and-hold (SH) circuit coupled to a first source having an output coupled to a reference arm of a comparator circuit;
a second SH circuit coupled to a second source having an output coupled to a test arm of a comparator circuit; wherein
the reference arm comprises a reference resistor and a reference winding comprising a fixed number of turns in series between the first SH circuit and ground; and
the test arm comprises a resistor and a variable winding comprising a variable number of turns in series between the second SH circuit and ground; and
the comparator circuit supports one or more of voltage reference measurements, current reference measurements and resistor reference measurements.

In accordance with an embodiment of the invention there is provided a device comprising:
a first sample-and-hold (SH) circuit coupled to a first source having an output coupled to a first node of a bridge circuit comprising the first node, a second node, a third node and a fourth node;
a second SH circuit coupled to a second source having an output coupled to the fourth node of the bridge circuit;
the bridge circuit comprising a first resistor coupled to the first node and the second node, a second resistor coupled to first node and the third node, a third resistor coupled to the second node and the fourth node and a fourth resistor coupled to the third node and the fourth node;
a first output port coupled to the second node; and
a second output port coupled to the third node; wherein
the first resistor comprises a plurality of resistors in parallel of which a subset of the plurality of resistors are electrically tunable; and
adjustment of the subset of the plurality of resistors provides for adjustment of a voltage divider comprising the first resistor and third resistor.

In accordance with an embodiment of the invention there is provided a device comprising:
an amplifier;
a first sample-and-hold (S/H) circuit coupled to an output of the amplifier by a first switch and to a first arm of a bridge or a null detector;
a second S/H circuit coupled to the output of the amplifier by the first switch and to a second arm of the bridge or null detector; and
a controller connected to the amplifier, the first switch, the first S/H circuit, the second switch and the second S/H circuit; wherein
the controller executes a process comprising the sequential steps of:
connecting the output of the amplifier to the first S/H circuit and connecting an input of the amplifier to a first source;
setting the first S/H circuit;
connecting the output of the amplifier to the second S/H circuit and connecting an input of the amplifier to a second source;
setting the second S/H circuit; and
connecting within a defined time period the first S/H circuit to the first arm of the bridge or null detector and the second S/H circuit to the second arm of the bridge or null detector.

In accordance with an embodiment of the invention there is provided a method comprising:
selectively coupling an amplifier to each of a pair of sample-and-hold (S/H) circuits to generate a pair of signals; and
coupling the pair of signals from the outputs of the pair of S/H circuits to a measurement circuit for performing a measurement; wherein
the outputs of the pair of S/H circuits are coupled to the circuit within a defined time period and each S/H circuit of the pair of S/H circuits is coupled to a defined port of the measurement circuit; and
the measurement circuit comprising a bridge selected from the group comprising a direct current comparator resistance bridge, a Wheatstone bridge, a dual source bridge and a null detector bridge circuit.

In accordance with an embodiment of the invention there is provided a method comprising:
providing a network of resistors in series and parallel;
providing a self-calibrating null detector; and
employing the self-calibrating null detector to generate a series of self-calibrated ratios of the resistors within the network of resistors; and
employing the series of self-calibrated rations to self-calibrate one or more electrical standards selected from the group comprising a resistance standard, a voltage standards and a current standard.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1A depicts a schematic of a self-calibrating multiple range voltage divider according to an embodiment of the invention;

FIG. 1B depicts a schematic of a self-calibrating multiple range voltage divider according to an embodiment of the invention;

FIG. 2A depicts a multi-range voltage divider circuit according to an embodiment of the invention with relays to isolate discrete resistors of the multiple resistors within each stage;

FIG. 2B depicts a multi-range voltage divider circuit according to an embodiment of the invention employing multiple resistors within each stage;

FIG. 3 depicts a resistive bridge according to an embodiment of the invention employing optical driving of the resistors within the resistive bridge;

FIG. 4 depicts a resistive bridge according to an embodiment of the invention employing optical driving of the resistors within the resistive bridge with a measurement head separated from the electrical test equipment;

FIG. 5 depicts a resistive bridge according to an embodiment of the invention employing optical driving of the resistors within the resistive bridge with a measurement head separated from the electrical test equipment which includes a null detector optically decoupled from the electrical test equipment and sample-hold circuits on the inputs;

FIG. 6 depicts a voltage divider circuit according to the design of FIG. 2A with a single stage according to an embodiment of the invention with calibration switches;

FIG. 7 depicts a multi-stage divider network providing multiple output ratios supporting embodiments of the invention;

FIG. 8 depicts a resistive bridge according to an embodiment of the invention employing an electrically tunable resistive element as part of a parallel resistor network within the resistive bridge;

FIG. 9 depicts a resistive bridge according to an embodiment of the invention employing dual sources in conjunction with sample and hold circuits;

FIG. 10 depicts a direct current comparator bridge according to an embodiment of the invention employing dual sources in conjunction with sample and hold circuits; and

FIGS. 11 and 12 depict direct current comparator bridges according to an embodiment of the invention employing a single amplifier in conjunction with sample and hold circuits.

### DETAILED DESCRIPTION

The present invention is directed to self-calibrating electrical standards for test in instruments exploiting null detection circuits for precision electrical measurements and precision transducers over current ranges from 1 mA or less to 20 kA or greater, voltage ranges of 1 V or less to 1000 kV or greater, resistance ranges from 1 μΩ or less to 10 PΩ or greater, and over frequency ranges from DC to hundreds of MHz.

The ensuing description provides exemplary embodiment(s) only, and is not intended to limit the scope, applicability or configuration of the disclosure. Rather, the ensuing description of the exemplary embodiment(s) will provide those skilled in the art with an enabling description for implementing an exemplary embodiment. It being understood that various changes may be made in the function and arrangement of elements without departing from the spirit and scope as set forth in the appended claims.

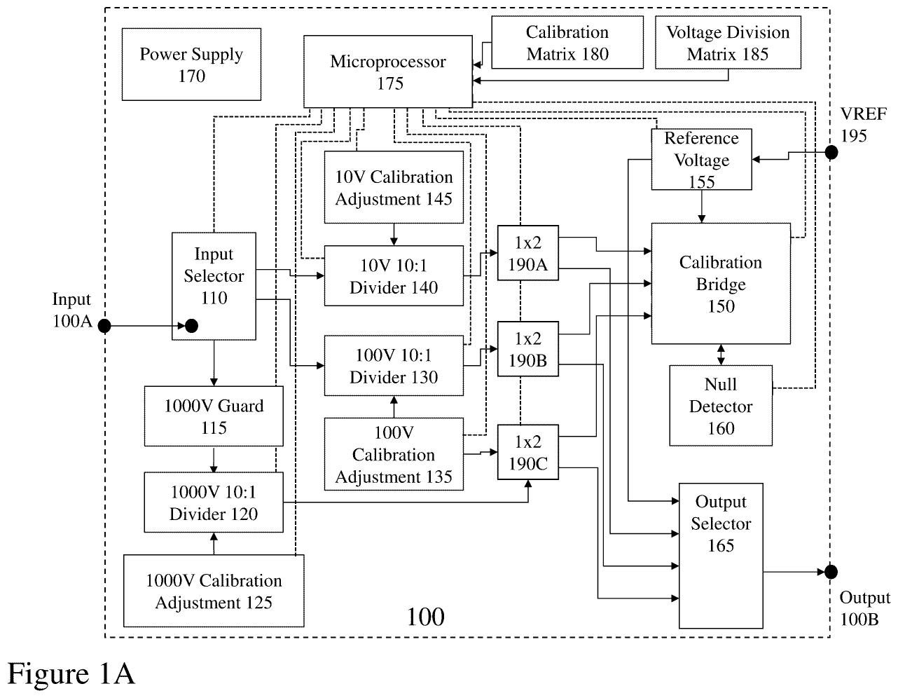

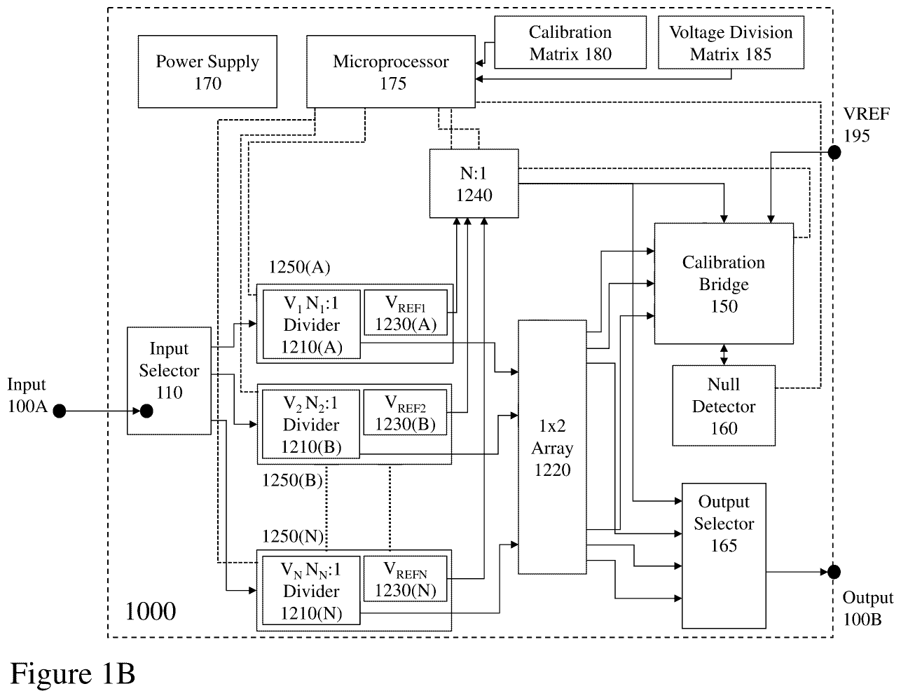

Referring to FIG. 1A there is depicted a schematic of a self-calibrating multiple range voltage divider (SC-MRVD) 100 according to an embodiment of the invention or supporting embodiments of the invention. Accordingly, an input 100A provides an electrical signal to be divided to an input selector 110 which is coupled to a microprocessor (μP) 175 for control signal provisioning. Based upon the μP 175 signal the received input electrical signal is coupled to either a first Divider 140, a 10V 10:1 divider; second Divider 130, a 100V 10:1 divider; and third Divider 120, a 1000V (1 kv) 10:1 divider. In some instances, e.g. third Divider 120, the divider may be coupled to the input via a protection and/or isolating circuit such as depicted with 1000V Guard 115 The outputs of the first to third Dividers 140 to 120 respectively are coupled to first to third switches 190A to 190C respectively that route the divided voltage from the respective divider to either the Calibration Bridge 150 or the Output Selector 165. The Output Selector 165 and first to third switches 190A to 190C respectively are also connected to the μP 175 allowing the configuration of the SC-MRVD 100 to be established. For operation as a divider during a measurement the SC-MRVD 100 is configured by the μP 175 such that the input 100A is coupled to and from the appropriate divider and therein to the output 100B.

Each of the first to third Dividers 140 to 120 respectively are in addition to being coupled to the Input Selector 110 and first to third switches 190A to 190C respectively are also coupled to a respective calibration adjustment circuit. With SC-MRVD 100 these are 10V Calibration Adjustment 145 coupled to the first Divider 140, 100V Calibration Adjustment 135 coupled to the second Divider 130, and 1000V Calibration Adjustment 125 coupled to third Divider 120. These calibration adjustment circuits are also connected to μP 175. A Reference Voltage circuit 155 is coupled to Calibration Bridge 150 and the Output Selector 165 whilst the Calibration Bridge is also connected to a Null Detector 160 which it itself coupled to the μP 175. Accordingly, the μP 175 can establish a calibration mode for one of the first to third Dividers 120 to 140 wherein the selected divider is coupled to the Calibration Bridge 150 via its associated switch of first to third switches 190A to 190C and its associated calibration adjustment circuit enabled.

Accordingly, in a calibration mode a known probe voltage is applied from the calibration adjustment circuit to its associated divider circuit and therein to the Calibration Bridge 150 which receives the Reference Voltage 155. The Calibration Bridge 150 providing signals to the Null Detector 160 and the output from the Null Detector 160 is read by the μP 175. Based upon the output from the Null Detector 160 the μP 175 may adjust the calibration of the divider circuit via the calibration adjustment circuit. Data relating to the calibration adjustments and voltage division circuits may be stored within matrices accessible by the μP 175, depicted as Calibration Matrix 180 and Voltage Division Matrix 185. These matrices may, for example, in addition to current calibration parameters store additional calibration characteristic information relating to aspects of the SC-MRVD 100 operation such as temperature, DC vs AC performance, input current, pressure, etc.

Accordingly, the SC-MRVD 100 when integrated into a TME system may perform a calibration routine automatically prior to any measurement with the TME system. Alternatively, the SC-MRVD 100 may exploit time dependent data within the matrices, Calibration Matrix 180 and Voltage Division Matrix 185, such that a series of measurements with a TME system with a single calibration of the associated divider may be performed. This calibration “frequency” may also be established, for example, based upon an indication of measurement accuracy during a configuration of the SC-VR-MD 100A within the TME. For example, to provide voltage divider accuracy at 20 ppb a calibration every measurement may be required whereas 50 ppb accuracy may allow multiple measurements within a 15-minute period provided ambient environmental conditions do not change outside predetermined limits, and 0.1 ppm (100 ppb) accuracy may allow measurements over a 2 hour period provided instrument stability for over an hour may be sufficient for measurements at provided ambient environmental conditions do not change outside a different set of predetermined limits.

The SC-MRVD 100 may also be configured to couple the internal voltage reference from Reference Voltage 155 to the output 100B or receive an external reference voltage at a port VREF 195. This port may, for example, be employed with an internal reference source, e.g. a temperate stabilized Zener diode, is insufficient at very low ppb accuracies thereby allowing an external voltage reference, e.g. a Josephson junction voltage reference. A power supply 170 is depicted which provides the stable power supplies for the different components within the SC-MRVD 100. Other elements that may be provided within the SC-MRVD 100 within different products offered exploiting the self-contained self-calibrating voltage divider concepts according to embodiments of the invention may include one or more communications interfaces to an external TME, front-panel touch panel configuration, front-panel display for configuration-status-measurement display, shielded and/or unshielded electrical connectors for input-output-VREF etc. As such elements do not impact the underlying self-contained self-calibrating voltage divider concept these have not been depicted within the schematic for the SC-MRVD 100.

It would be evident that the resulting SC-MRVD 100 is a self-contained self-calibrating voltage divider wherein the underlying accuracy of calibration is now determined by the accuracy of the null detector circuit. Accordingly, within another embodiment of the invention at the highest accuracies, e.g. few 10s of ppb, an external null circuit may be employed or an alternate null circuit design for a high accuracy SC-MRVD 100.

Now referring to FIG. 1B there is depicted a schematic for a self-calibrating module voltage divider (SC-MVD) 1000. Accordingly, as depicted multiple divider reference modules 1250(A) to 1250(N) may be inserted within the chassis of the SC-MVD 1200. Each divider reference modules 1250(A) to 1250(N) comprising a respective voltage divider 1210(A) to 1210(N) and voltage reference source 1230(A) to 1230(N). Each voltage divider 1210(A) to 1210(N) comprising a voltage divider circuit and its associated calibration adjustment circuit. For example, if voltage divider 1210(A) were a 100V 10:1 divider it would comprise 100V 10:1 Divider 130 as depicted in FIG. 1A and 100V Calibration Adjustment 135 as depicted in FIG. 1A. The associated voltage reference source 1230(A) may for example be Reference Voltage 155 in FIG. 1A. In this manner each divider reference modules 1250(A) to 1250(N) is self-contained.

Accordingly, under the control of the μP 175 the output of a divider reference module is coupled either to the Output 100B via the Output Selector 165 and 1×2 Array 1220 or coupled to the Calibration Bridge 150 via the 1×2 Array 1220. In the calibration mode with the divider reference modules 1250(A) to 1250(N) coupled to the Calibration Bridge 150 the voltage reference within the divider reference modules 1250(A) to 1250(N) is also coupled to the Calibration Bridge 150 via N:1 switch 1240. Accordingly, the μP 175 is coupled to matrices such as Calibration Matrix 180 and Voltage Division Matrix 185 whilst the Calibration Bridge 150 is connected to Null Detector 160 and may accept an external reference voltage via VREF 195. Further the input 100A is coupled to Input Selector 110. It would be evident that within other embodiments of the invention the Null Detector 160 and/or Calibration Bridge 150 may be modular allowing the SC-MVD 200 to operate at different accuracies according to the module employed. Further, multiple detection modules each with Null Detector 160 and Calibration Bridge 150 may be employed with multiple inputs simultaneously if the N:1 switch 1240 is replaced with an N×M switch (N divider reference modules and M detection modules) and a N×(M+1) switch replacing the 1×2 Array 1220.

Whilst the Calibration Bridge 150 is depicted in FIGS. 1A and 1B as being coupled via the switches to each divider it would be evident that a N×1 switch may alternatively be employed as a selector circuit disposed between the Calibration Bridge 150 and the multiple divider circuits.

Optionally SC-MRVD 100 in FIG. 1A may have additional ports/interfaces on the Input Selector 110, 1×2 switches, Calibration Bridge 150 or intervening selector circuit etc. such that it may be expanded further from an initially purchased configuration.

Optionally, either SC-MRVD 100 in FIG. 1A and/or SC-MVD 1000 in FIG. 1B may exploit multiple Calibration Bridges 150 such that each Calibration Bridge 150 is specifically designed/optimized for its associated voltage divider.

Optionally, each divider reference module may include a switch acting as a mode selector switch such that the output of the voltage divider reference is either coupled to the Output Selector 165 or the Calibration Bridge 150.

Each of the self-calibrating multiple range voltage dividers depicted in FIGS. 1A and 1B, namely SC-MRVD 100 and SC-MRVD 1000 respectively exploit multiple voltage dividers. Within SC-MRVD 100 these are a first Divider 140 (10V 10:1 divider), second Divider 130 (100V 10:1 divider), and third Divider 120 (1 kV 10:1 divider) each coupled to a calibration adjustment circuit, being 10V Calibration Adjustment 145, 100V Calibration Adjustment 135, and 1 kV Calibration Adjustment 125. Within SC-MRVD 1000 these are divider reference modules 1250(A) to 1250(N) having different ratios, N₁:1 to N_{N}:1 respectively, each having an associated voltage reference circuit, being voltage reference sources 1230(A) to 1230(N) respectively.

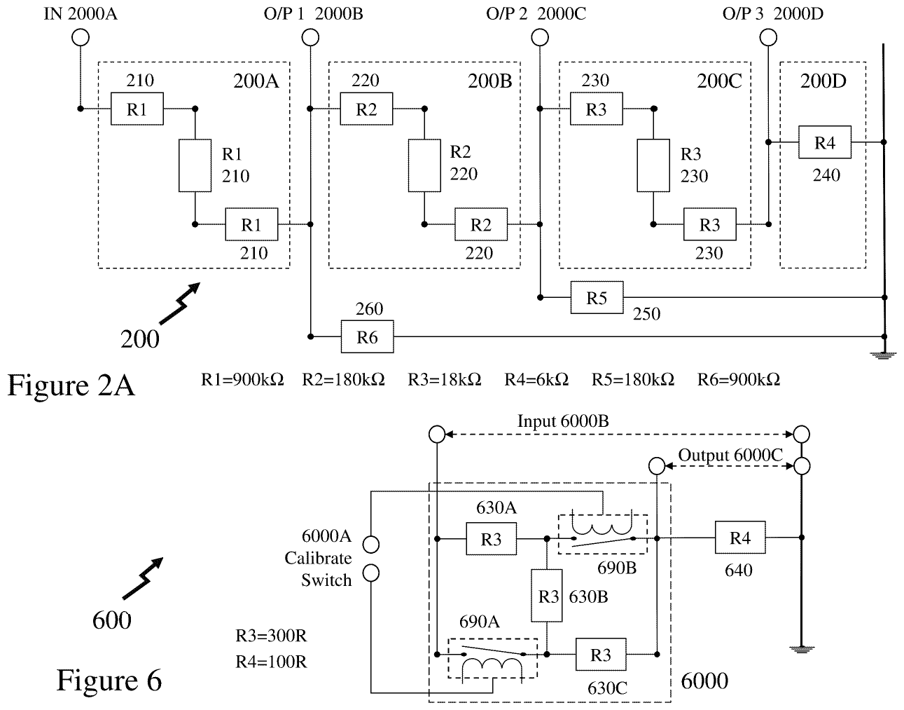

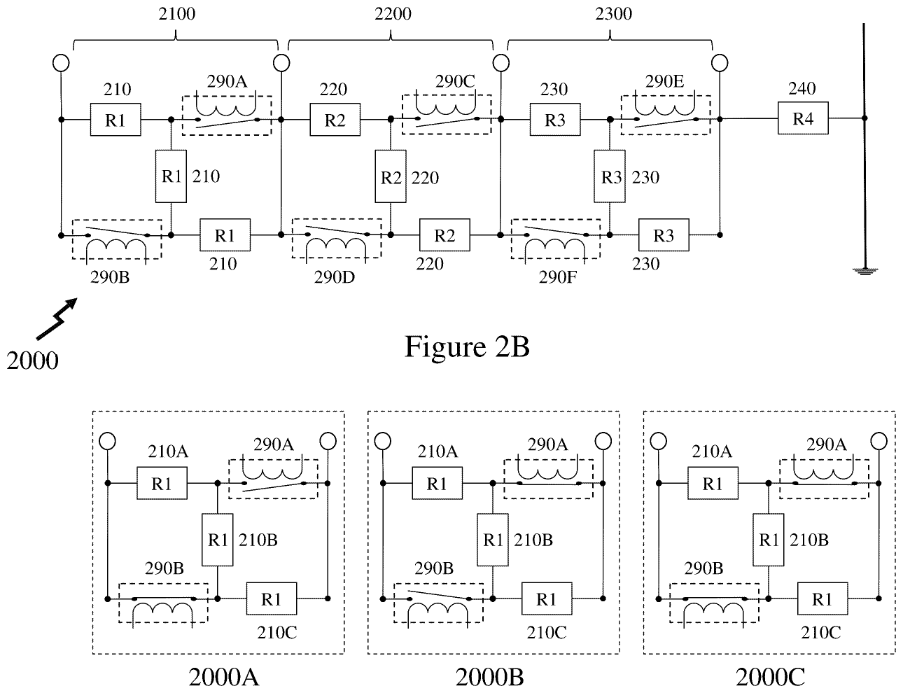

Now referring to FIG. 2A there is depicted a MRVDC 200 according to an embodiment of the invention using first to fourth resistor networks 200A to 200D respectively disposed between the input 2000A, IN, and ground. Disposed between each pair of the first to fourth resistor networks 200A to 200D respectively are first to third output taps O/P 1 2000B, O/P 2 2000C, and O/P 3 2000D respectively.

First to fourth resistor networks 200A to 200D respectively comprise:
First resistor network 200A formed from three first resistors R1 210 in series;
Second resistor network 200B formed from three second resistors R2 220 in series;
Third resistor network 200C formed from three third resistors R3 230 in series;
Fourth resistor network 200D comprising single fourth resistor R4 240.

However, in contrast to prior art multi-range voltage divider circuits the multi-range voltage divider circuit 200 now also comprises resistors disposed between the ground rail and each of the O/P 2 2000C and O/P 1 2000B points respectively. These being fifth resistor R5 250 and sixth resistor R6 260. Now with R1=150 R, R2=22.5 R, R3=3 R, R4=R, R5=30 R and R6=150 R then O/P 1 2000B is 1:10 divided relative to the input voltage at input (IN) 2000A. Further, O/P 2 2000C is then by 1:10 divided, and O/P 3 2000D is 1:100 relative to O/P 1 200B and hence divided 1:100 and 1:1000 respectively relative to IN 2000A. Accordingly, the multiple voltage divider 200 provides three divided outputs simultaneously relative to the input voltage divided by 10, 100, and 1000 respectively. With R=6 kΩ the input impedance of IN 2000A is 3MΩ.

Alternatively, other designs may be implemented such as:
Variant 1: R1=1.8MΩ, R2=270 kΩ, R3=40.5 kΩ, R4=13.5 kΩ, R5=270 kΩ, and R6=1.8MΩ; and
Variant 2: R1=1.2MΩ, R2=180 kΩ, R3=27 kΩ, R4=9 kΩ, R5=180 kΩ, and R6=1.2MΩ.

Now referring to FIG. 2B there is depicted a MRVDC 2000 according to an embodiment of the invention with relays within each stage to isolate the discrete resistors of the multiple resistors within each stage. Accordingly, within each stage there are a pair of relays, first and second relays 290A and 290B within the first Stage 2100, third and fourth relays 290C and 290D within the second Stage 2200, and fifth and sixth relays 290E and 290F within the third Stage 2300. Each of the relays adds a resistance when closed which should be corrected for. Accordingly, as depicted in first to third images 2000A to 2000C respectively representing first Stage 2100 in three configurations, these being:
First image 2000A with first relay 290A open and second relay 290B closed such that only resistor 210C is disposed across the first Stage 2100 rather than all 3 resistors 210A, 210B and 210C;
Second image 2000B with first relay 290A closed and second relay 290B open such that only resistor 210A is disposed across the first Stage 2100 rather than all 3 resistors 210A, 210B and 210C; and
Third image 2000C with first relay 290A closed and second relay 290B closed such that only resistor 210B is disposed across the first Stage 2100 rather than all 3 resistors 210A, 210B and 210C.

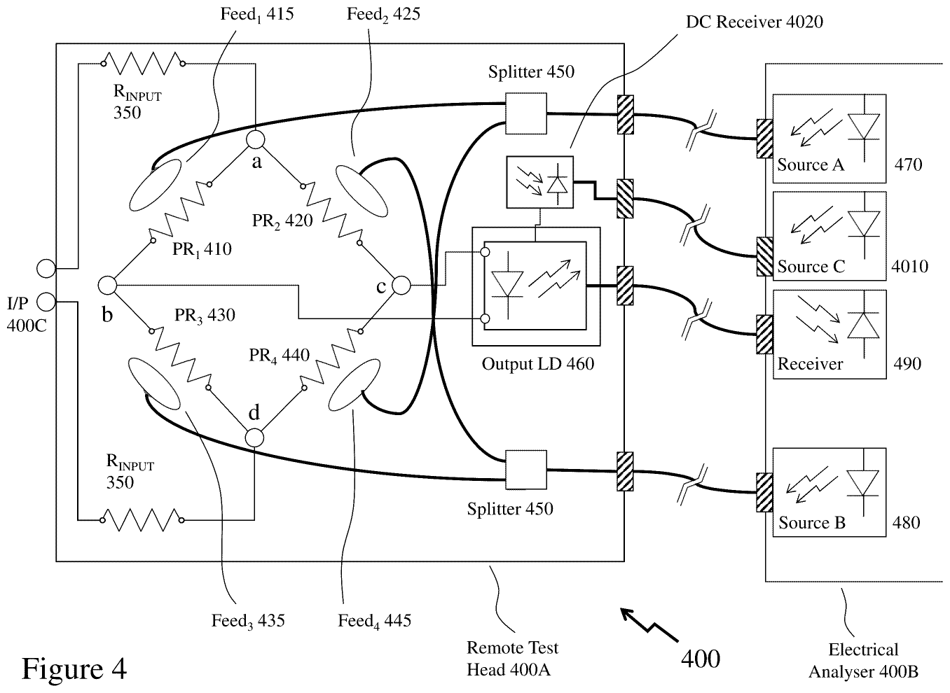

It would be evident to one of skill in the art that the tolerance of the division ratios within prior art MRVDC 300 and MRVDC 400 are dependent upon the tolerances of resistors employed. Within electrical test instruments the requirements regularly require accuracies within the sub-part per million (ppm) range, e.g. 0.1 ppm to 1.0 ppm. In comparison ultra-high precision resistors typically only offer tolerances of ±50 ppm, temperature coefficients of ±15 ppm/° C., and lifetime drift of similar levels. For high precision test applications to provide the required accuracy of the MRVDC 400 and allow for balancing of the calibration bridge and/or a measurement bridge, compensating for ageing, correcting for relay resistances (c.f. FIG. 4B) and some compensation of tolerances the inventors note that adjustment circuits such as depicted by the adjustment circuits in “Methods and Devices for High Stability Precision Voltage Dividers”, issued as U.S., European and Canadian patents including U.S. Pat. Nos. 10,353,045 and 10,746,837 respectively, may be employed within such embodiments of the invention. The design steps of the establishment of the resistor values within the adjustment circuits may be based, for example, upon establishing an initial instrument condition wherein at start of life the potentiometers are set to the middle of their resistance range and the desired range of adjustment in ppm and resistance, for example. Other design criteria may be established within other implementations and embodiments of the invention.

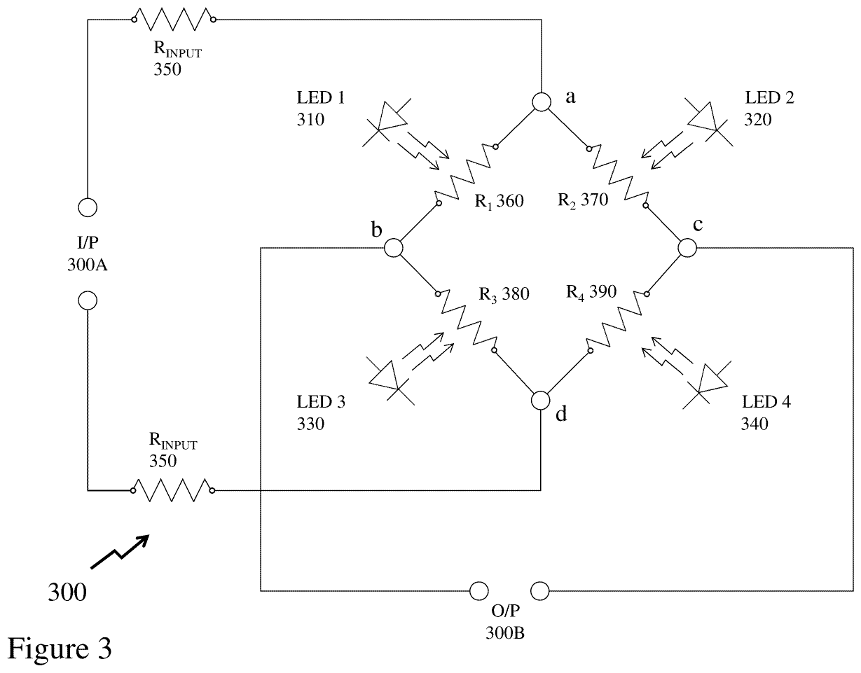

Within the prior art Wheatstone bridge circuit (Bridge) is used to measure an unknown electrical resistance by balancing two legs of a bridge circuit wherein one leg of the bridge circuit includes an unknown component. Referring to FIG. 3 the Bridge comprises a first leg between node a and node d disposed across an input voltage, V on Input 300A, comprising R1 360 and R3 380 and a second leg also disposed between node a and node d across the input voltage, V, comprising R2 370 and R4 390. The output, G at Output 400B, being measured across nodes b and c. Accordingly, the relationship between G and V is defined by Equation (1). Hence, knowing R1 360, R2 370, and R4 390 allows determination of R3 370 or where R3 370 is variable, R1 360 and R2 370 are known then R4 390 can be found based upon adjusting R3 380 until G=0.

$$\frac{G}{V} = \frac{{R}_{2} {R}_{3} + {R}_{1} {R}_{4}}{( {R}_{1} + {R}_{3} ) + ( {R}_{2} + {R}_{4} )} \qquad ( 1 )$$

Accordingly, when measuring the scenario where G=0 then the output from the Bridge is today typically coupled to an electrical multimeter. However, an electrical multimeter if employed as a null detector is not an appropriate selection as the “zero” state of the electrical multimeter moves and therefore the apparently determined null will not be the null shortly thereafter as the electrical multimeter drifts. This arises in part from the large number of protection circuits within a multi-function electrical multimeter that result in a large number of leakage currents within the electrical multimeter which impact the measurement circuits when seeking to make an “absolute” null measurement. Accordingly, the meter at the Output 300B may be replaced with a null detector such as described and depicted below in respect of embodiments of the invention.

The inventors have previously established an inventive bridge circuit such as depicted in FIG. 3 by Bridge Circuit 300 operating according to an embodiment of the invention and supporting embodiments of the invention where optical driving of the resistors within the resistive bridge is employed, see for example “Null Detector Devices and Systems Exploiting Same”, issued as U.S., European and Canadian patents including U.S. Pat. No. 10,845,394. The Bridge Circuit 300 satisfies underlying design goals wherein the exploitation of dual “optical chopping” provides for a balanced circuit relative to the input and wherein high frequency “optical chopping” provides for improved timing information.

Within the design methodology of the inventors then two key areas are addressed with respect to the null detector concepts and bridge circuits employing such null detectors. Firstly, the design methodology addresses the need to minimize crosstalk from any modulating signals employed within the circuit(s) so that these do not affect the source which the circuits are trying to balance. In order to achieve this the inventors exploit proper shaping of the modulating drive signal(s) such as described and depicted in “Null Detector Devices and Systems Exploiting Same.” Secondly, it is important to isolate modulator and detector circuits from the output of any instrument employing the null detector concepts and bridge circuits according to embodiments of the invention to minimize input bias current which is addressed within null detector concepts and bridge circuits by using optical isolation between the relevant circuit portions such as described and depicted in respect of FIGS. 3 to 5 respectively.

Accordingly, as depicted Bridge Circuit 300 comprises an input 300A which is coupled to the bridge via input resistors, R_{INPUT}, and an output 300B. The bridge itself comprises first to fourth photoresistive elements (PREs) R1 360, R2 370, R3 380, R4 390 respectively which are optically illuminated by first to fourth optical sources LED1 310, LED2 320, LED3 330, and LED4 340 respectively. Consider an initial case that each of the first to fourth optical sources LED1 310, LED2 320, LED3 330, and LED4 340 respectively are off and that R4 is in fact an unknown. Accordingly, if LED3 330 is now activated then the resistance of the third PRE R3 380 will vary and the output 300B can be monitored to determine when a null is obtained and hence based upon the known characteristics of the third PRE R3 380 and the output of the third optical source LED3 330 the value of the third PRE R3 380 when the output is nulled can be determined. As the third optical source LED3 330 can be varied under control of a microprocessor or microcontroller then the null detection process can be automated. Alternatively, different PREs can be activated or within other embodiments of the invention only part of the Bridge Circuit 300 employs PREs instead of fixed resistors or electrical potentiometers.

A photoresistive element (PRE), also known as a photoresistor, light-dependent resistor (LDR), or photo-conductive cell, is a light-controlled variable resistor. The resistance of a photoresistor decreases with increasing incident light intensity; in other words, it exhibits photoconductivity. A photoresistor is made of a high resistance semiconductor such that in the dark, a PRE can have a resistance as high as several megaohms (MΩ), while in the light, a photoresistor can have a resistance as low as a few ohms according to the design. If incident light on a photoresistor exceeds a certain frequency, photons absorbed by the semiconductor give bound electrons enough energy to jump into the conduction band. The resulting free electrons (and their hole partners) conduct electricity, thereby lowering resistance. The resistance range and sensitivity of a photoresistor can substantially differ among dissimilar devices. Moreover, unique photoresistors may react substantially differently to photons within certain wavelength bands. Alternatively a PRE may be photodiode or phototransistor although these have higher non-linearity than that of an LDR and mat exploit either an intrinsic semiconductor or an extrinsic semiconductor.

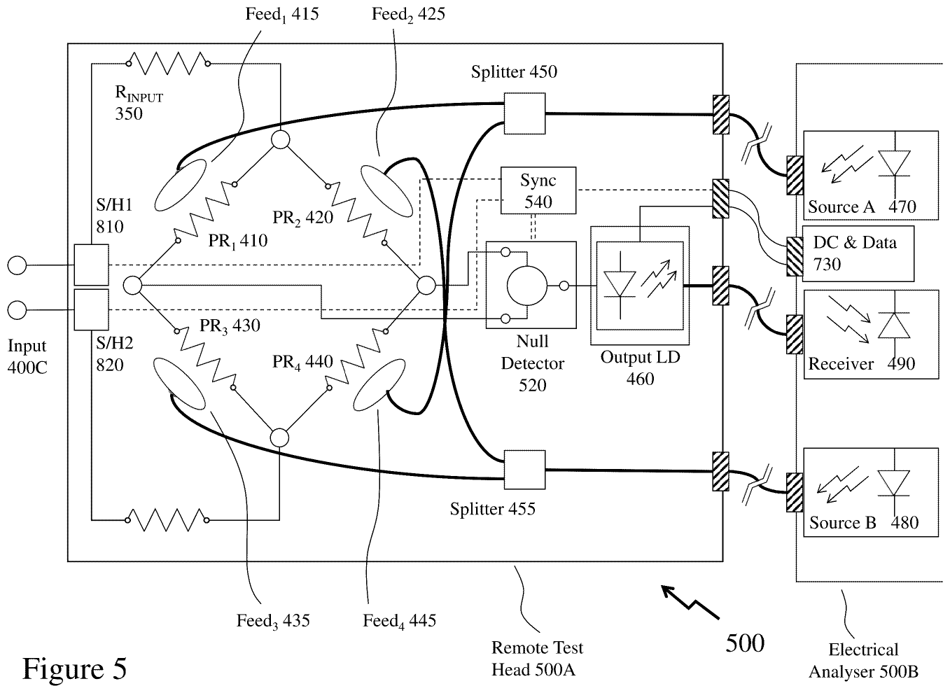

In order to achieve a design goal of providing a balanced input bridge circuit according to embodiments of the invention the inventors exploit dual choppers illuminating the PREs and employ pre-distortion of the optical signals coupled to the PREs in order to exploit the characteristics of the PRE to establish fast response, better sensitivity etc. as discussed in “Null Detector Devices and Systems Exploiting Same.” However, the invention can be implemented without the use of a chopper. Whilst embodiments of the invention depicted in FIGS. 4 and 5 below are for a remote measurement head coupled to an electrical analyser (electrical measurement equipment) it would be evident that the remote test heads may be integrated within the electrical analyser.

Accordingly, referring to FIG. 4 depicts a Test Instrument 400 comprising a Remote Test Head (RTH) 400A according to an embodiment of the invention employing optical driving of the resistors within the resistive bridge with a measurement head separated from the electrical test equipment. Accordingly, the RTH 400A is coupled to the Electrical Analyser (ELEAL) 400B via optical connections and a single electrical link. As depicted a first optical emitter Source A 470 is coupled from the ELEAL 400B to the RTH 400A and therein to first splitter 450 from which the outputs are coupled to first PRE (PR1) 410 and fourth PRE (PR4) 440. A second optical emitter Source B 480 is coupled from the ELEAL 400B to the RTH 400A and therein to second splitter 455 from which the outputs are coupled to second PRE (PR2) 420 and third PRE (PR3) 430. Each of the first to fourth PREs R1 410, R2 420, R3 430, and R4 440 are coupled to their respective optical source via first to fourth Optical Feeds, Feed1 415, Feed2 425, Feed3 435, and Feed4 445. The Input 400C being coupled to the bridge circuit via Input Resistors, R_{INPUT} 350. In order to isolate the Electrical Analyser 400B from the RTH 400A the output of the bridge circuit across port b to c (the Input 400C being applied to ports a and d) drive Output LD 460 which transmits an optical signal proportional to the output voltage across node b and c to the ELEAL 400B. Source C 4010 within the ELEAL 400B and DC Receiver 4020 within the RTH 500A provide an optical link to deliver optical power for generating the necessary current to drive the Output LD 460. The optical power delivery may be a power-over-fiber system (or power-by-light) according to an industry standard or non-standard system.

Whilst the RTH 400A is depicted as remote from the ELEAL 400B it would be evident that the RTH 400A may be integrated within the ELEAL 400B but would in this instance be electrically isolated and floating relative to the ELEAL 400B.

It would be evident that depending upon the optical fiber loss characteristics, optical wavelength, optical power etc. required for the LDRs that the RTH 400A or 500A in FIGS. 4 and 5 can be physically employed at different maximum distances from the ELEAL such as 1 m (3 feet), 2 meters (6.5 feet), 5 meters (feet), 10 meters (16 feet), 50 meters (164 feet), 100 meters (328 feet), 500 m (1,640 feet) and 1000 meters (3,280 feet, 0.6 mile), or more.

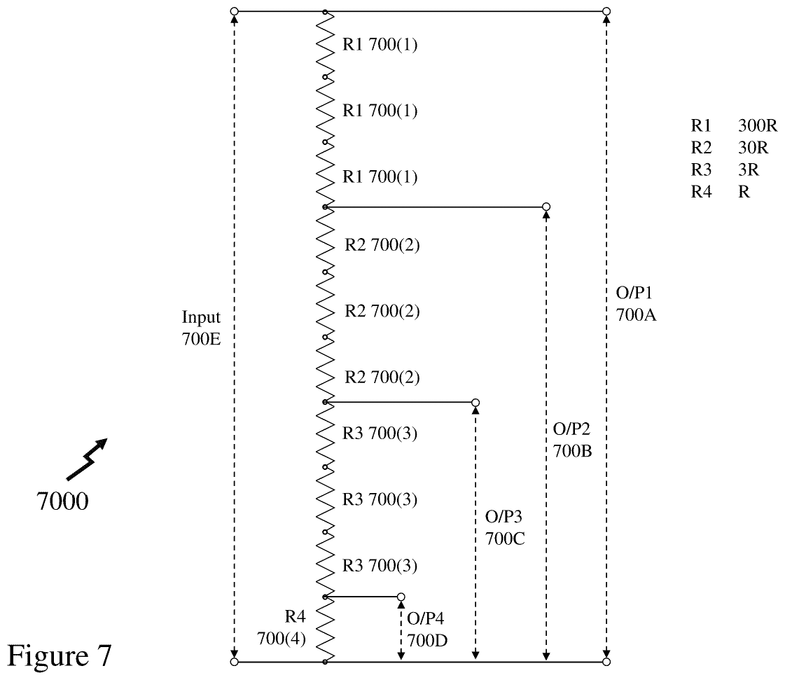

As depicted in FIG. 6 with first traces 600A the outputs of Optical Source A 470 and Optical Source B 480 as employed within ELEAL 400B and ELEAL500B in FIGS. 4 and 5 respectively are depicted. It is evident that these are the inverse of one another with a time offset δt and repetition period Δt, the latter leading to a repetition frequency f₀=1/Δt. Accordingly, the PREs are driven by their respecting optical sources to either increase in resistance (reducing optical illumination) or decrease in resistance (increasing optical illumination). Accordingly, the output voltage is a function of optical illumination at the frequency, f₀. Whilst embodiments of the invention may exploit PREs formed from LDRs these can be replaced with photodetectors in order to increase f₀ which may in some embodiments of the invention be beneficial to reduce noise within the measurement. Accordingly, as depicted a “predistortion” or shaping of the optical illumination waveform may lead to improved linearity in PRE resistance versus time for the transitions whilst driving each pair of PREs provides for no change in the load of the RTH to the input.

The Output LD 460 may be coupled to the output of the bridge circuit via a low power analog-to-digital converter (ADC) for transmission to the ELEAL. Optionally, the electrical link or optical link providing power to the Output LD 460 and its associated electronics may be eliminated and this portion of the RTH powered by a battery.

In applications where noise performance is important then the thermal noise of the RTH or the bridge circuit if integrated within the ELEAL may become important. In such instances, the RTH or bridge circuit may be cooled. Optionally, the cooling may be applied through one or more Peltier elements including, for example, multi-stage Peltier elements, or heat pumps etc. Within other embodiments the RTH or bridge circuit may include a conductive plate coupled to a Dewar vessel forming part of the RTH or ELEAL allowing the cooling to be through filling the Dewar with chlorodifluoromethane refrigerant R-22 (−48.6° C.) or liquid nitrogen (−196° C.) or exploiting subliming carbon dioxide (−78.5° C.).

Optionally, the Input 400C of the RTH 400A in FIG. 4 may employ protection circuitry in order to limit the voltage applied to the bridge portion. For example, Zener diodes may be employed as well as transient-voltage-suppression (TVS) diodes.

Within embodiments of the invention the optical sources, e.g. Source A 470 and Source B 480 may be coupled to the RTHs 400A respectively by optical fibers that are selected in dependence upon the characteristics of the optical emitter/source employed such as singlemode versus multimode, operating wavelength, output power etc. For example, singlemode silica optical fibers may be employed for singlemode visible and near-infrared sources (e.g. 850 nm, 1300 nm, 1550 nm) with typical cores of approximately 10 μm; or multimode silica optical fibers may be employed for multimode visible and near-infrared sources with cores typically 50μ, 62.5μ, 100 μm as well as 200 μm, 300 μm, 365 μm, 400 μm, 550 μm, 600 μm, 800 μm, 940 μm, 1000 μm. 1500 μm and 2000 μm for ultraviolet, visible and near-infrared wavelengths in silica and/or polymer. These may be terminated with collimating optical assemblies to provide Feed 1 415, Feed 2 425, Feed 3 435, and Feed 4 445 with different numerical aperture, beam diameter, etc. as well as lenses etc. Optionally, a single optical fiber may be replaced with an array of optical fibers such as hexagonally packed, rectangularly packed, etc. to provide different beam profiles to couple to the photodiode, phototransistor or LDR. Optionally, the profile of the illumination may be non-uniform where the behaviour of the LDR dictates this.

These optical fibers may be coated with protective polymer coatings and individually cabled with additional physical protection layers such as Kevlar™ and plastic jackets and bundled with further physical protection layers or they may be bundled within a single protective outer either within a single common inner tube or individually within discrete tubes. A single optical connector assembly may be employed in some embodiments whilst in other embodiments two or more optical connectors may be employed. Such connectors may be industry standard formats such as E-2000, FC, MIC, MPO/MTP, SC, SMA, and ST for example as well as many others including industry standard and custom connectors.

Within embodiments of the invention the optical wavelength range employed may be a single optical wavelength (e.g. 533 nm, 850 nm, 1300 nm etc.), multiple optical wavelengths, a broadband emission such as from a superluminescent diode. Examples of optical sources may include semiconductor diodes such as light emitting diodes (LEDs), laser diodes (LDs), vertical cavity surface emitting lasers (VCSELs), gas lasers such as helium-neon (633 nm), Argon ion (multiple wavelengths but commonly 488 nm and 514 nm), krypton laser (multiple wavelengths but commonly 470 nm, 480 nm and 520 nm), helium-cadmium (442 nm), copper vapour (510 nm and 578 nm), carbon dioxide (10.6 μm) and solid state lasers such as diode pumped neodymium-doped yttrium aluminum garnet (Nd:YAG) (1.064 μm). Semiconductor diodes may exploit InGaN (445-465 nm), AlGaInP (635-760 nm), GaAlAs (785-850 nm), AlGaAs (1063 nm), InGaAsP (1310-650 nm) as well as other semiconductors. The figures in brackets are common wavelengths for these semiconductors and do not reflect the range of wavelengths achievable through composition adjustments. Optical powers may vary according to laser type and design from milliwatts (mW) to hundreds of milliwatts (100 s mW), watts (W) to hundreds of Watts and kilowatts (kW).

As depicted within FIGS. 3 and 4 respectively the input, e.g. Input 300A or Input 400C is depicted as a pair of contacts coupled to an upper signal rail and a lower signal rail (not depicted for clarity) such that the bridge circuit or RTH can float with the input rails. Optionally, a rail may be grounded wherein any series resistor between the input and the bridge circuit may be eliminated.

Within FIG. 4 the four resistors are depicted as being coupled to a pair of optical sources each of which are optically split to couple to the pair of resistors each optical source is coupled to. Optionally, the splitter may be within the ELEAL rather than the RTH or alternatively four optical sources may be employed within the ELEAL each coupled to one of the LDRs wherein the four optical sources are driven as two pairs through synchronized drive signals.

Accordingly, whilst the descriptions above describe and depict a system it would be evident that a method may be implemented for configuring an electrical test measurement by providing a resistive bridge circuit comprised of light dependent resistors or light dependent diodes which is then driven through applying optical pulse signals to drive the bridge resistive bridge circuit. In this manner an electrical test measurement may be performed at a point remote from the test instrument with optical isolation of the measurement head from the test instrument. Based upon the electrical measurement being performed a controller within the test instrument may adjust aspects of the optical pulses applied such as repetition frequency, pulse profile, and upper/lower limits of illumination.

Within the descriptions above in respect of embodiments of the invention with respect to a system comprising a resistive bridge circuit in conjunction with a null detector no specific distinction has been made as to whether the devices and/or systems exploiting embodiments of the invention receive direct current (DC) or alternating current (AC) signals. Typically, within the prior art such resistive bridge circuits and null detectors are employed upon DC signals. However, the inventors have established variants of the system which allow for the systems and/or devices according to embodiments of the invention to operate with AC signals.

According to an embodiment of the invention devices and/or systems according to embodiments of the invention may exploit built in synchronization within the devices and/or systems, for example via hardware or firmware, so that two input AC signals, whether current or voltage, can be synchronized prior to comparing the signals via the internal optical bridge and determining the null point. The two input AC signals may be the same frequency, or they may have different frequencies, but their currents or voltages may be compared.

With respect to determining which portion of the applied AC signal is employed to determine the AC null point then this may be any portion of the AC signal as defined by the hardware or firmware. Optionally, the portion of the AC signal employed may be varied within other devices and/or systems according to embodiments of the invention through a selection with respect to the device and/or system itself or through a selection by an external controller in communication with a processor forming part of the device and/or system. Accordingly, the portion of the AC signal may be the positive amplitude magnitude, negative amplitude magnitude, or other portions of the AC signal. Further, within other embodiments of the invention the determination of an AC signal with respect to the null point with respect to the cross-over position of the synchronized signal(s), or unsynchronized signal(s) then the devices and/or systems may be configured to one determination method or they may provide configurability with respect to the determination method. Examples of determination methods may comprise a zero crossing method or a root-mean-square (RMS) method or other predetermined portions.

Within embodiments of the invention a sample-and-hold circuit may be employed for both DC and AC signals so that the null point is determined based on the signal “released” by the sample-and-hold circuit. It would be evident that therefore a sample-and-hold circuit is provided for each input signal. One such sample-and-hold circuit may be based upon the use of a capacitor based circuit which would charge up based on the AC, or DC signal. Accordingly, the capacitance charge level could then be fed into the optical bridge and compared. Beneficially, this would allow an AC signal to be compared with or without having the two input AC circuits synchronized.

Now referring to FIG. 5 there is depicted a resistive bridge according to an embodiment of the invention employing optical driving of the resistors within the resistive bridge with a Measurement Head 500A separated from the Electrical Analyser 500B. The Measurement Head 500A includes a Null Detector 520 which is coupled to the Output LD 460 so that it is optically decoupled from the TME. The Null Detector 520 is coupled to a Sync Circuit 540 within the Measurement Head 700A which is coupled to a DC & Data Circuit 530 within the Electrical Analyser which now provides DC power to the Sync 540 and Null Detector 520 together with the Output LD 460 but also provides clock and/or data signals to the Sync 540. Additionally, the Inputs 400C are now coupled to first and second sample-hold circuits S/H1 510 and S/H2 520 respectively which are coupled to the Sync Circuit 740 so that these can be “gated” or clocked to provide the signals to the resistive bridge as described above. Within an embodiment of the invention the DC & Data Circuit 530 is electrically coupled between the Electrical Analyser 500B and the Remote Test Head 500A whilst within other embodiments of the invention the connections may be optical for data signals and electrical for DC power or optical for both power and data signals.

Accordingly, the resistive bridge within some embodiments of the invention may be decoupled from the electrical test equipment with the optical connections between the measurement head and the electrical test equipment and the null detector is within the electrical test equipment.

Accordingly, the resistive bridge and null detector within some embodiments of the invention may be decoupled from the electrical test equipment with the optical connections between the measurement head and the electrical test equipment with full optical decoupling for all signals including any DC power. In other embodiments of the invention the optical decoupling may be for all AC signals with only DC electrical power between the measurement head and electrical test equipment. Within other embodiments of the invention the optical decoupling may be for all optical signals to the resistive bridge and from an integrated null detector with only DC power and AC data being electrically provided between the measurement head and the electrical test equipment. Optionally, data signals and/or DC power may also be coupled to the measurement head using one or more wireless interfaces according to embodiments of the invention.

The Remote Test Head (RTH) 400A in FIG. 4 and Measurement Head 500A in FIG. 5 provide for a bridge and null detector, such as Calibration Bridge 150 and Null Detector 160 in FIGS. 1A and 1B respectively, which form part of a self-calibrating multiple range voltage divider (SC-MRVD) 100 in FIG. 1A or SC-MRVD 1000 in FIG. 1B or another item of TME. As discussed above the Remote Test Heads (RTH) 400A and 500A in FIGS. 4 and 5 provide the bridge and null detector, such as Calibration Bridge 150 and Null Detector 160 in FIGS. 1A and 1B respectively, either integral with or remote to the SC-MRVDs 100 and 1000 in FIGS. 1A and 1B respectively.

Accordingly, the inventors have established based upon resistive divider networks, such as described and depicted in FIGS. 2A and 2B respectively and “Methods and Devices for High Stability Precision Voltage Dividers”, and bridge-null detector circuits, such as depicted in FIGS. 3 to 5 respectively and “Null Detector Devices and Systems Exploiting Same” designs for and methods of implementing a series of self-calibrating standards for voltage, resistance and current as described and depicted in respect of FIGS. 6 to 8 respectively.

Whilst within the following descriptions embodiments are described with respect to establishing 1:10 ratios and particular resistor values (ohmic values) it would be evident that different ohmic values may be employed for the divider network(s) in order to establish a different ratio, and thus provide non-decade values. Further, the switching employed for self-calibrations may also allow the user to select from the available multiple outputs which when combined with microprocessor control (either internal or external) can provide for automated measurement setups.

### Multi-Value Voltage Standard

An exemplary requirement of a test and measurement system may be, for example, calibrating an internal voltage reference, e.g. a Zener diode voltage reference, which requires calibration. Accordingly, a calibrated value is employed to measure and adjust one or more other voltage outputs based on a divider network and a bridge such as an internal Wheatstone bridge or external. For example, the voltage source may be a 100 V source or a 1000 V (1 kV) source or other value depending upon the available standard voltage source and resistive divider network. Considering, for example a 100 V reference then this may be divided down to 10 V for comparison against a 10 V reference calibrated value where the 10 V calibrated value is then transferred to the 100 V reference.

Optionally, a variable voltage source may be employed rather than a fixed voltage sources and self-calibrated with a system according to an embodiment of the invention at several voltage levels based on divider ratios supported by the system. Accordingly, based upon these self-calibrated voltage levels the system may interpolate between them to provide a calibrated output voltage at any value within the supported range.

### Multi-Value Resistance Standard

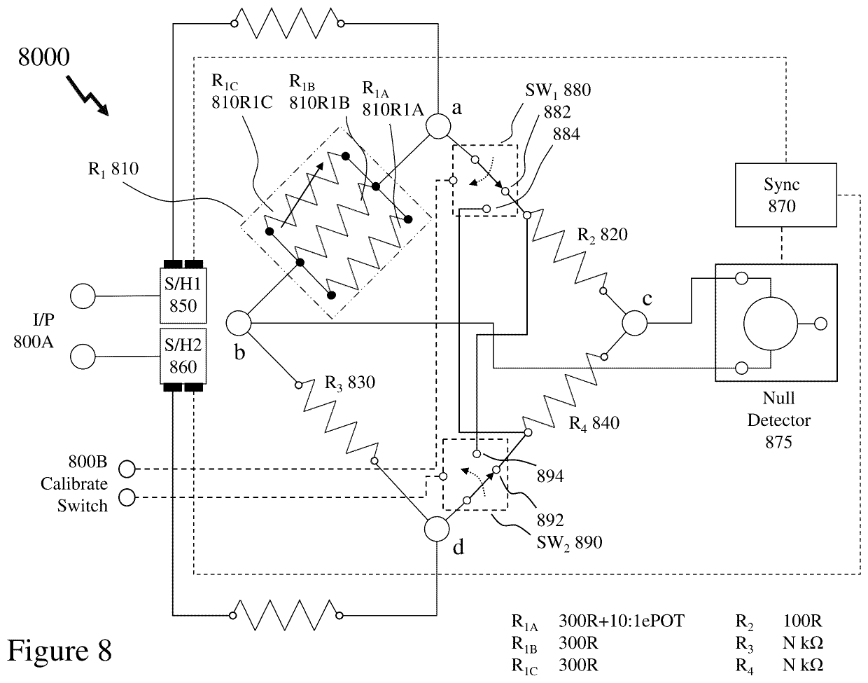

An exemplary requirement of a test and measurement system may be, for example, a resistance standard which requires calibration, e.g. a 1Ω resistor. Accordingly, a calibrated resistance standard can be employed to calibrate other reference standards forming part of or associated with an item of TME via a bridge, e.g. an internal Wheatstone bridge, in conjunction with an internal voltage source, and a null detector as described and depicted in FIGS. 6 and 7.

Referring to FIG. 6 there is depicted an exemplary Divider 600 based upon 1 R and 3 R ohmic values. As depicted the Divider 600 comprises a Divider Network 6000 and R4 resistor 640, equivalent to third Stage 2300 and R4 240 of the MRVDC 2000 in FIG. 2B. Accordingly, an input 6000B is divided by the Resistive Divider 6000 in conjunction with R4 640 to yield Output 6000C. Resistive Divider 6000 comprising in series between first, second and third R3 resistors 630A to 630C respectively. Where R3=300 R and R4=100 R then the Resistive Divider 6000 provides an Output 6000C which is the Input 6000B divided by 10. Disposed across the first R3 resistor 630A is first Switch 690A and across the third R3 resistor 630C a second Switch 690B. Each of the first Switch 690A and second Switch 690B being connected to Calibrate Switch ports 6000A such that the first R3 resistor 630A and/or third R3 resistor 630C can be bypassed for calibrating the Resistive Divider 6000.

Accordingly, of R=1Ω then a system according to an embodiment of the invention can be employed to calibrate a 10 R (i.e. 10Ω) via a Divider comprising 1 R, 3 R, 3 R and 3 R as described and depicted in FIG. 6. Accordingly, multiple 1:10 ratios can be calibrated to provide a wider range of decade value resistance standards.

Further, exemplary embodiments of the invention may be employed to calibrate more than one ohmic value, e.g. 1 Ω, 10 kΩ, etc., in order to expand to a wider range of decade value resistance standards. For example, a calibrated 1Ω resistor may be employed to calibrate 10 Ω, 100 Ω, 1 kΩ and then a calibrated 10 kΩ resistor may be employed to calibrate 100 kΩ, 1 MΩ, 10Ω; etc.

Referring to FIG. 7 there is depicted a Divider Network 7000 comprising an Input 700E and first to fourth Outputs O/P1 TO O/P4 700A to 700D respectively. The Divider Network 7000 comprising a serial connection of 3 R1 700(1) resistors, 3 R2 700(2) resistors, 3 R3 700(3) resistors and 1 R4 700(4). First O/P1 700A being across all of these resistors such that O/P1 700A is a 1:1 output of Input 700E. For example, R1=300 R, R2=30 R, R3=3 R and R4=R.

Second O/P2 700B being across the 3 R2 700(2) resistors, 3 R3 700(3) resistors and 1 R4 700(4) such that second O/P2 700B is a 10:1 output of the Input 700E. Third O/P3 700C being across the 3 R3 700(3) resistors and 1 R4 700(4) such that second O/P2 700B is a 100:1 output of the Input 700E. Fourth O/P4 700D being across R4 700(4) such that fourth O/P4 700D is a 1000:1 output of the Input 700E.

### Multi-Value Current Standard

An exemplary requirement of a test and measurement system may be, for example, a current standard which requires calibration. Accordingly, through a combination of a Multi-Value Resistance Standard, such as described above, in combination with a calibrated Voltage Reference then an item of TME can generate selectable calibrated currents based upon I=V/R through the user of different selected different resistors within the Multi-Value Resistance

### Standard.

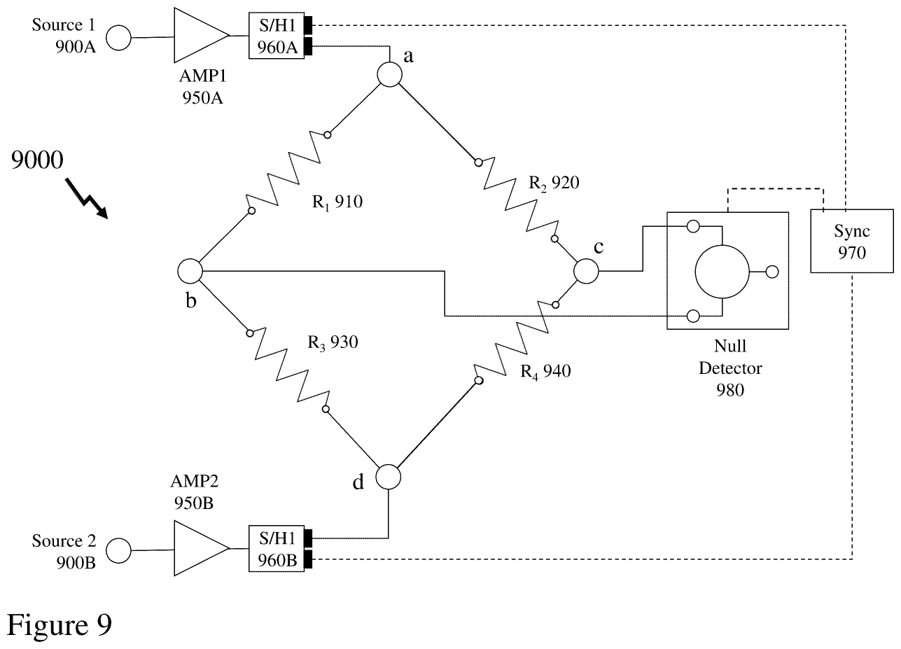

Referring to FIG. 8 there is depicted a schematic of a Self-Aligning Voltage Divider (SAVD) 8000 according to an embodiment of the invention which employs an electrically tunable resistive element as part of a parallel resistor network within the resistive bridge. As depicted the SAVD 8000 comprises an Input (I/P) 800A which is coupled to first and second sample-hold circuits S/H1 850 and S/H2 860 respectively which are coupled to the Sync Circuit 870 so that these can be “gated” or clocked to provide the signals to the resistive bridge at nodes a and d respectively. A Null Detector 875 is coupled across nodes b and c of the resistive bridge and therein to the Sync Circuit 870.

The resistive bridge comprises Tunable Resistor Network R1 810 between nodes a and b, first Resistor R2 820 between nodes a and c, second Resistor R3 830 between nodes b and d and third Resistor R4 840 between nodes c and d. As depicted the Tunable Resistor Network R1 810 comprises a pair of Fixed Resistors R1A 810R1A and RIB 810R1B in parallel with each other and with a Tunable Resistor R1C 810R1C. The Tunable Resistor R1C 810R1C comprising fixed Resistor and electronically controlled potentiometer (ePOT), e.g. an EPOT with 10:1 tuning range. The EPOT allows the Tunable Resistor Network R1 810 to be configured such that the bridge can provide different ratios as well as provide for returning the bridge to an original calibration.

For example, consider R2 820=N kΩ, R4 840=N kΩ, R3 830=100 R, R1A 810R1A=300 R, R1B 810R1B=300 R and R1C 810R1C=300 R+10:1 EPOT. This allows the left hand side of the bridge comprising Tunable Resistor Network R1 810 and R3 830 within the SAVD 800 to provide a 1:10 ratio such that the SAVD 800 is a 10:1 voltage divider and allows through tuning of the EPOT for the original calibration to be restored under electrical control. Other dividing ranges may be supported by adjustment of resistor values, ePOT etc.

Optionally, one or both of the pair of Fixed Resistors R1A 810R1A and R1B 810R1B may be comprise a fixed resistor and an ePOT. Optionally, the third Tunable Resistor 810R1C 810C may comprise a series of ePOTs discretely or in combination with one or more fixed resistors.

Optionally each of the pair of Fixed Resistors R1A 810R1A and RIB 810R1B and Tunable Resistor R1C 810R1C may each comprise a series of ePOTs discretely or in combination with one or more fixed resistors. The fixed resistors, the ePOT resistor value and ePOT tuning range may be common in each instance or different.

Optionally, the EPOT may be replaced with one or more photoresistive elements (PREs) as described above in respect of FIGS. 4 and 5 for example allowing the SAVD 8000 to be remote as described above allowing the SAVD 8000 to be employed in electrically noisy environments etc.

Optionally, the first Resistor R2 820, second Resistor R3 830 and third Resistor R4 840 may be one or more PREs as described above in respect of FIGS. 4 and 5 for example allowing the SAVD 8000 to be remote as described above allowing the SAVD 8000 to be employed in electrically noisy environments etc.

Optionally, the second Resistor R3 830 may comprise another Tunable Resistor Network such as Tunable Resistor Network R1 810 allowing the voltage divider to handle different divisions or ranges.

The SAVD 8000 comprises a first Switch SW1 880 disposed between node a and first Resistor R2 820 and a second Switch SW2 890 disposed between node d and third Resistor R4 840. First Switch SW1 880 being a 1×2 switch with a first Port 882 coupled to the first Resistor R2 820 and a second Port 884 coupled to the end of third Resistor R4 840 to which the second Switch SW2 890 is connected. Similarly, the second Switch SW2 890 is another 1×2 switch with a third Port 892 coupled to the third Resistor R4 840 and a fourth Port 894 coupled to the end of first Resistor R2 820 to which the first Switch SW1 880 is connected.

Each of the first Switch SW1 880 and second Switch SW2 890 being connected to Calibrate Switch Ports 800B. Accordingly, the bridge can be configured to connect nodes a and d to node c via the first Resistor R2 820 discretely, the third Resistor R4 840 discretely, the first Resistor R2 820 and third Resistor R4 840 respectively or the third Resistor R4 840 and first Resistor R2 820 respectively.

Within another embodiment of the invention the SAVD 8000 may omit the first and second sample-hold circuits S/H1 850 and S/H2 860 respectively and Sync Circuit 870.

Embodiments of the invention may exploit a resistance standard within a temperature controlled chamber. For example, a 100Ω standard platinum resistor may be employed or a 25≠ platinum resistor employed with 4:1 ratio divider.

Embodiments of the invention may exploit a quantum Hall resistor as the resistance standard, this having a resistance of 25 kΩ (25812.807Ω) or other ohmic value.

Within embodiments of the invention the calibration electrical value, e.g. resistance, voltage or current, may be a low level and ratios employed within the TME to support calibration of higher electrical levels, e.g. higher resistances, voltages or currents.

Within embodiments of the invention the calibration electrical value, e.g. resistance, voltage or current, may be a high level and ratios employed within the TME to support calibration of lower electrical levels, e.g. higher resistances, voltages or currents.

Within embodiments of the invention the calibration electrical value, e.g. resistance, voltage or current, may be at a moderate high level and ratios employed within the TME to support calibration of higher and lower electrical levels, e.g. higher and lower resistances, voltages or currents.

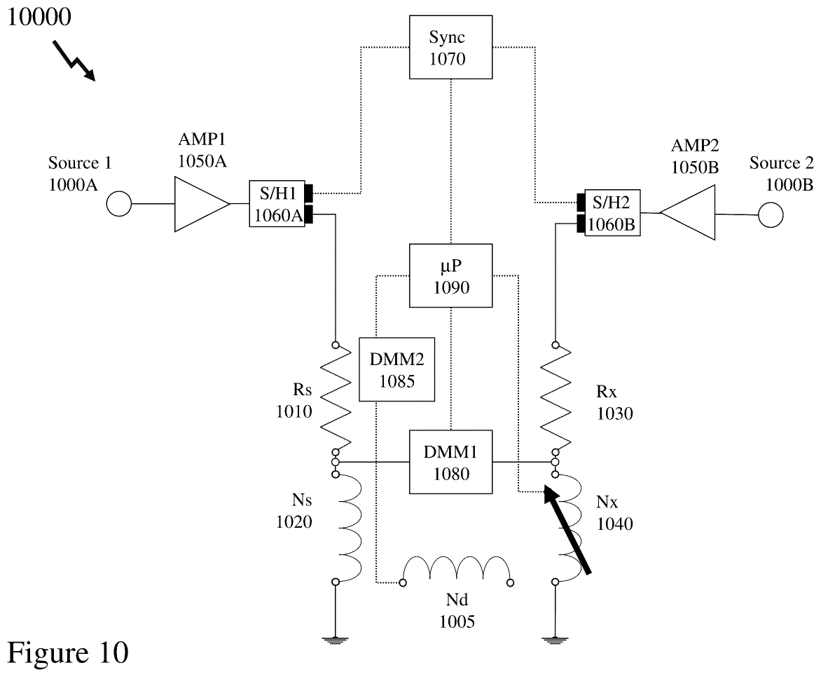

Now referring to FIG. 9 there is depicted a Schematic 9000 of a bridge circuit according to an embodiment of the invention employing dual sources, e.g. dual voltage or dual current sources. As depicted a first Source (Source 1) 900A is coupled via a first Amplifier (AMP 1) 950A to a first Sample-and-Hold Circuit (S/H1) 960A and therein to node a of the bridge. Similarly, a second Source (Source 2) 900B is coupled via a second Amplifier (AMP 2) 950B to a second Sample-and-Hold Circuit (S/H2) 960B and therein to node d of the bridge. The bridge comprising R1 910 between nodes a and b, R2 920 between nodes a and c, R3 930 between nodes b and d and R4 940 between nodes c and d. A Null Detector 980 is connected across nodes b and c. Each of S/H1 960A, S/H2 960B and Null Detector 980 are connected to a Synchronization Circuit (Sync) 970 which provides the necessary control and timing signals.

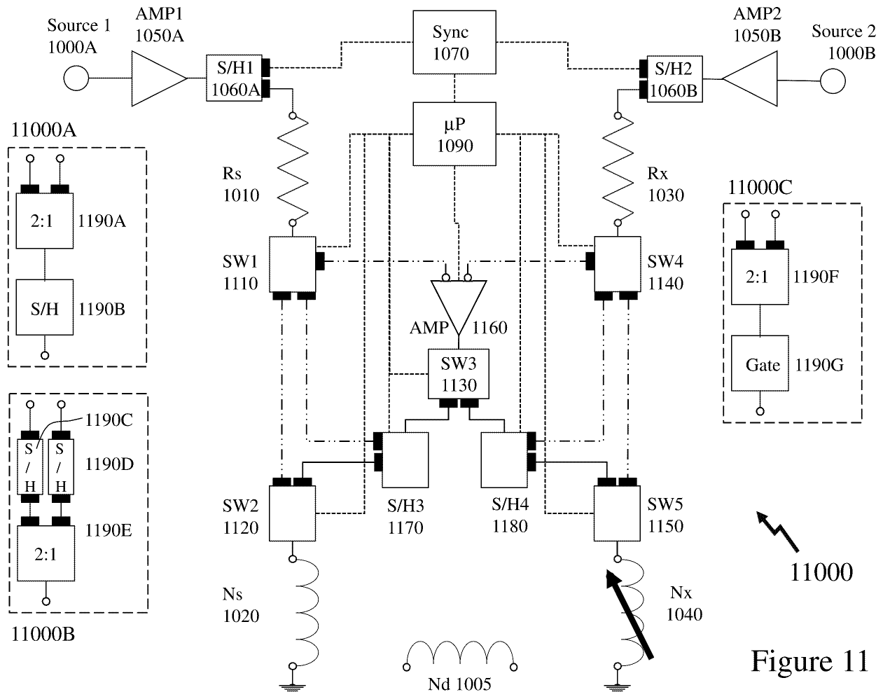

FIG. 10 depicts a Direct Current Comparator (DCC) Bridge 10000 according to an embodiment of the invention employing dual sources, e.g. dual voltage sources.

As depicted a first Source (Source 1) 1000A is coupled via a first Amplifier (AMP 1) 1050A to a first Sample-and-Hold Circuit (S/H1) 1060A and therein to ground via a reference resistor Rs 1010 and the reference turns Ns 1020 of a winding around a magnetic core. Similarly, a second Source (Source 2) 1000B is coupled via a second Amplifier (AMP 2) 1050B to a second Sample-and-Hold Circuit (S/H2) 1060B and therein to ground via the unknown resistor Rx 1030 and the variable number of turns Nx 1040 of another winding around the magnetic core. A first digital multimeter (DMM1) 1080 is connected between the Rx 1010 and Ns 1020 on one side and Rx 1030 and Nx 1040 on the other side. A Flux Detector Nd measures the imbalance in magnetic flux with the magnetic core induced by the current flowing through the reference turns Ns 1020 generated by the first Source 1 1000A through the reference resistor Rs 1010 and the current flowing through the variable number of turns Nx 1040 induced by the current flowing as by the second Source 2 1000B and unknown resistance Rx 1030. Accordingly, closed loop control from the Microprocessor (μP) 1090 can adjust the DCC 10000 such that the error signal is minimized thereby allowing the unknown resistance Rx 1030 to be determined where the error is read by the μP from a second DMM (DMM2) 1085. The μP 1090 is connected to a Sync Circuit 1070 which is coupled to S/H1 1060 and S/H2 1070, DMM2 1085 and the variable number of turns Nx 1040 such that the number of turns on that arm is adjusted under electrical control from the μP 1090. The Sync Circuit 1070 synchronizing at least the S/H1 1060 and S/H2 1070.

Optionally, DMM1 1080 may be replaced with a null detector as described and depicted within this specification or as known in the art.

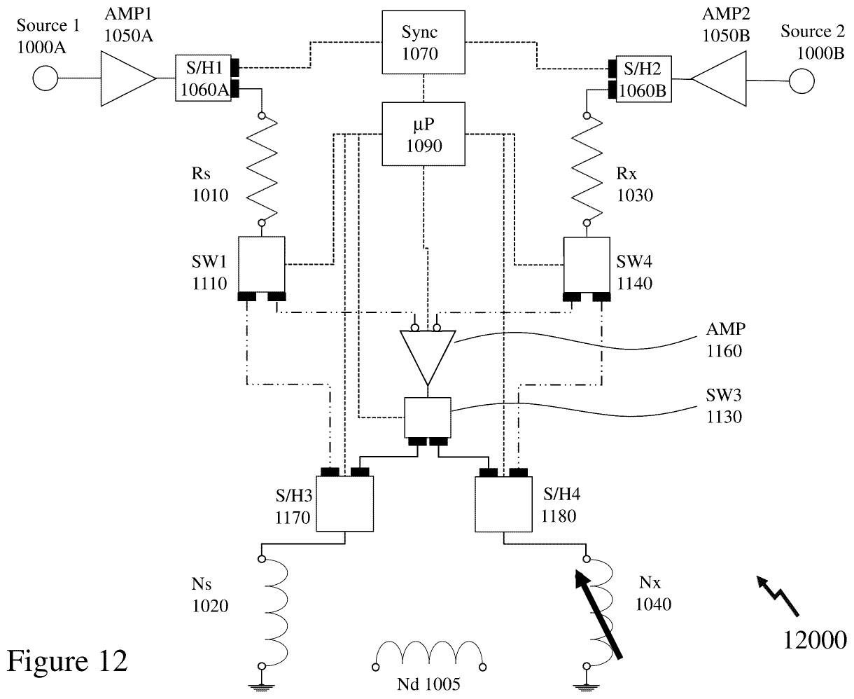

Now referring to FIG. 11 there is depicted a DCC Bridge 11000 according to an embodiment of the invention employing a single amplifier in conjunction with Sample-and-Hold circuits.

As depicted a first Source (Source 1) 1000A is coupled via a first Amplifier (AMP 1) 1050A to a first Sample-and-Hold Circuit (SH1) 1060A and therein to a reference resistor Rs 1010. The reference resistor Rs 1010 rather than being directly to ground via the reference turns Ns 1020 of a winding around a magnetic core is coupled to a first switch SW1 1110 and therein to the reference turns Ns 1020 via a second switch SW2 1120 or from the first switch SW1 1110 to Amplifier 1160 and therein via third switch SW3 1130 to third Sample-and-Hold Circuit (SH3) 1170 and then to the reference turns Ns 1020 via the second switch SW2 1120 or from SW1 1110 to third switch SW3 1130 and then to the reference turns Ns 1020 via the second switch SW2 1120. The first switch SW1 1110, second switch SW2 1130, third switch SW 1130 and third Sample-and-Hold Circuit (SH3) 1170 being coupled to a Microprocessor (μP) 1090 to define whether Source 1 1000A is coupled via the Amplifier 1160 or not.

Similarly, a second Source (Source 2) 1000B is coupled via a second Amplifier (AMP 2) 1050B to a second Sample-and-Hold Circuit (S/H2) 1060B and therein to the unknown resistor Rx 1030. The unknown resistor Rx 1030 rather than being directly to ground via the variable turns Nx 1040 (i.e. the number of turns carrying current is variable) of another winding around the magnetic core is coupled to a fourth switch SW4 1140 and therein to the variable turns Nx 1040 via a fifth switch SW5 1150 or from the fourth switch SW4 1150 to Amplifier (AMP) 1160 and therein via third switch SW3 1130 to fourth Sample-and-Hold Circuit (SH4) 1180 and then to the variable turns Nx 1040 via the fifth switch SW5 1150 or from the fourth switch SW4 1150 to fourth Sample-and-Hold Circuit (SH4) 1180 and then to the variable turns Nx 1040 via the fifth switch SW5 1150.

The fourth switch SW4 1140, fifth switch SW5 1150, fourth Sample-and-Hold Circuit (SH4) 1180 and the variable turns Nx 1040 being coupled to the Microprocessor (μP) 1090 to define whether Source 2 1000B is coupled via the Amplifier 1160 or not.

In common with the DCC Bridge 10000 in FIG. 10 a digital multimeter (DMM1), not depicted for clarity, may be connected between a point between second switch SW2 1120 reference turns Ns 1020 and another point between the fifth switch SW5 1150 and variable turns Nx 1040 where the DMM1 is connected to the μP 1090. Also depicted is a Flux Detector Nd which measures the imbalance in magnetic flux with the magnetic core induced by the current flowing through the reference turns Ns 1020 and the current flowing through the variable turns Nx 1040 which is connected to a second digital multimeter (DMM2), not depicted for clarity, which is similarly connected to the μP 1090. Accordingly, the DCC 11000 can automatically adjust the number of turns of variable turns Nx 1040 such that the error signal is minimized thereby allowing the unknown resistance Rx 1030 to be determined where the error is read by the μP from DMM2. The μP 1090 is also connected to a Sync Circuit 1070 which is coupled to S/H1 1060 and S/H2 1070 (and SH3 1170 and Sh4 1180 whose links to the Sync Circuit 1070 are not depicted for clarity). Optionally, the Sync Circuit 1070 may form part of an overall control circuit (controller) with μP 1090 or may be implemented by the μP 1090.

The μP 1090 is connected to the first switch SW1 1110, second switch SW2 1120, third switch SW3 1130, fourth switch SW4 1140, fifth switch SW5 1150 and Amplifier (AMP) 1160. Optionally, DMM1, equivalent to DMM1 1080 in DCC Bridge 10000, may be replaced with a null detector as described and depicted within this specification or as known in the art.

Whilst within FIG. 11 each of the SH3 and SH4 are depicted as having dual inputs and single output, e.g. SH3 is connected to either SW1 1110 or SW3 1130 according to configuration and SH4 is connected to either SW4 1140 and SW3 1130 according to configuration, such that they either have dual Sample-and-Hold circuits before a 2×1 switch or a 2×1 switch before a single Sample-and-Hold circuit it would be evident that alternate configurations may be employed with discrete switches separate from the Sample-and-Hold elements for example. These options being depicted within first and second Inserts 11000A and 11000B respectively. Within first Insert 11000A SH3 1170 and SH4 1180 are depicted as being constructed with a 2:1 Switch 1190A and a single S/H 1190B whilst within second Insert 11000B the design employs first and second S/H 1190Cand 1190D with a 2:1 Switch 1190E.

Within the DCC Bridge 11000 depicted in FIG. 11 the S/H1 1060A and S/H2 1060 may be omitted within other embodiments of the invention.

Further, other configurations of switching may be employed to achieve a subset of the functionality and configurations without departing from the scope of the invention. For example, referring to DCC Bridge 12000 in FIG. 12 the direct connection configuration between reference resistor Rs 1010 and reference turns Ns 1020 and the direct connection configuration between unknown resistor Rx 1030 and variable turns Nx 1040 are now not implemented.

As depicted in DCC Bridge 11000 the Amplifier (AMP) 106—is placed after the resistors, namely Rs 1010 and Rx 1030 as if an amplified current were to be injected into the reference resistor and resistance being measured, Rs 1010 and Rx 1030 respectively, it may damage one or both of these resistors, “fry” them as colloquially known to those of skill in the art.

In operation the DCC Bridge 11000 operates by a process comprising:
initially establishing the balancing circuit open (i.e. not connected to either input signal, namely Source 1 1000A and Source 2 1000B respectively;
switching in Source1 1000A to the AMP 1060;
amplify Source1 1000A with AMP 1060;
hold the output of the AMP 1060 using SH3 1170 (but still not connecting to the balancing circuit);
disconnecting Source1 1000A from the AMP 1060;
switching in Source 2 1000B to AMP 1060;
amplifying Source2 1000B with AMP 1060;
hold the output of the AMP 1060 using SH4 1180 (but still not connecting to the balancing circuit);
connecting SH3 1170 to reference turns Ns 1020 and SH4 1180 to variable turns Nx 1040;
balance the DCC Bridge 11000 by adjusting the variable turns Nx 1040;
disconnecting the SH3 1170 and SH4 1180; and
repeat with another set of input signals.

Whilst the process described begins with Source 1 1000A and then proceeds to Source 2 1000B it would be evident to one of skill in the art that the process may begin with Source 2 1000B and then proceeds with Source 1 1000A.

Accordingly, the amplification is implemented via a single amplifier, e.g. AMP 1160 in FIG. 11, just before the signals are coupled to the balancing circuit, implemented for example by reference turns Ns 1020 and variable turns Nx 11050 in FIG. 11, such that the amplification is implemented one or more of:
prior to the electrical input of a bridge, e.g. a Wheatstone bridge;
separately to the current before input to the transformers/toroid (for example) on a DCC resistance bridge;
separately to the voltage before inputs to a dual source voltage bridge;
separately to the voltage before inputs to a null detector;
separately to the electrical input to the optical sources employed on either side of an optical based bridge (such as depicted in FIGS. 3 to 5 respectively) or optical null detector; or
after the optical sources either side of an optical bridge or optical null detector, wherein the AMP 1160 would be an optical amplifier, e.g. an erbium doped fiber amplifier (EDFA), semiconductor optical amplifier (SOA) etc., rather than an electrical amplifier, employed for the output from each of the optical sources (e.g. laser diodes (LDs), light emitting diodes (LEDs) etc.), along with two optical Sample-and-Hold circuits.

The designs depicted in FIGS. 11 and 12, in order to avoid instability in the bridge should both connect the reference and unknown sides concurrently (or within a defined period of time according to the characteristics of the bridge) and not connect any signal prior to the outputs from both of the Sample-and-Hold circuits being established. Accordingly, whilst the functionality depicted within FIGS. 11 and 12 is of N:1 and 1:N switches, where N is a positive integer, then the switch functionality may be implemented as having N+1 states. For example for a 1:N switch the N+1 states comprise N states with respect to connecting the input to the N outputs and the +1 state is where the input is not connected to any output. Similarly, for a N:1 switch the N+1 states comprise N states with respect to connecting to the N inputs to the output and the +1 state is where the output is not connected to any input port.

Alternatively the switches may employ a gate or gates to disconnect the switch until the microprocessor determines the settings of the two Sample-and-Hold circuits have been established. Such a switch being depicted in third Insert 11000C in FIG. 11 wherein a 2:1 switch is depicted as comprising 2:1 element 1190F and a Gate 1190G.

Within FIGS. 11 and 12 the AMP 1160 is depicted as having dual input ports coupled to SW1 1110 and SW4 1140. Within embodiments of the invention the AMP 1160 may be a dual input amplifier with gates to block or decouple one input port or the other or it may have a single input and a 2:1 switch is implemented between it and the two S/H circuits.

It would be evident that the amplification concept depicted in FIGS. 11 and 12 may be applied to any bridge or null detector circuit (i.e. could be for a DCC resistance bridge as depicted or for a dual source bridge, for a single source bridge, or for a null detector).

The Rs and Ns combination providing a reference arm of a comparator whilst Rx and Nx provide a test arm of the comparator. The concept of the embodiments of FIGS. 9 and 10 may also be applied to a dual source high resistance bridges without departing from the scope of the invention. The concepts described and depicted with respect to FIGS. 9 and 10 may be employed in TME for voltage reference measurements, current reference measurements and resistor reference measurements.

Specific details are given in the above description to provide a thorough understanding of the embodiments. However, it is understood that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

Implementation of the techniques, blocks, steps and means described above may be done in various ways. For example, these techniques, blocks, steps and means may be implemented in hardware, software, or a combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described above and/or a combination thereof.

Also, it is noted that the embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be rearranged. A process is terminated when its operations are completed, but could have additional steps not included in the figure. A process may correspond to a method, a function, a procedure, a subroutine, a subprogram, etc. When a process corresponds to a function, its termination corresponds to a return of the function to the calling function or the main function.

The foregoing disclosure of the exemplary embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the scope of the present invention.

What is claimed is:

1. A device comprising:
a first sample-and-hold (SH) circuit.

2. The device according to claim 1, wherein
the first sample-and-hold (SH) circuit is coupled to the upper signal rail having an output coupled to a first node of a bridge circuit comprising the first node, a second node, a third node and a fourth node; and
the device further comprises:
an input port comprising an upper signal rail and a lower signal rail;
a second SH circuit coupled to the lower signal rail having an output coupled to the second node of the bridge circuit;
the bridge circuit comprising
a first resistor coupled to the first node and the second node;
a second resistor coupled to first node and the third node;
a third resistor coupled to the second node and the fourth node;
a fourth resistor coupled to the third node and the fourth node;
a first output port coupled to the second node; and
a second output port coupled to the third node;
the first resistor comprises a plurality of resistors in parallel of which a subset of the plurality of resistors are electrically tunable; and
adjustment of the subset of the plurality of resistors provides for adjustment of a voltage divider comprising the first resistor and third resistor.

3. The device according to claim 2, further comprising
a first switch disposed between the fourth node and the fourth resistor wherein the first switch is configurable to a first state and a second state; wherein
in the first state the first switch electrically connects the fourth node and the fourth resistor; and
in the second state the first switch electrically connects the fourth node to an end of the second resistor distal to the other end of the second resistor coupled to the third node.

4. The device according to claim 2, further comprising
a first switch disposed between the first node and the second resistor wherein the first switch is configurable to a first state and a second state; wherein
in the first state the first switch electrically connects the first node and the second resistor; and
in the second state the first switch electrically connects the first node to an end of the fourth resistor distal to the other end of the fourth resistor coupled to the third node.

5. The device according to claim 2, further comprising
a first switch disposed between the fourth node and the fourth resistor wherein the first switch is configurable to a first state and a second state; and
a second switch disposed between the first node and the second resistor wherein the first switch is configurable to a third state and a fourth state; wherein
in the first state the first switch electrically connects the fourth node and the fourth resistor; and
in the second state the first switch electrically connects the fourth node to an end of the second resistor distal to the other end of the second resistor coupled to the third node.
in the third state the second switch electrically connects the first node and the second resistor; and
in the fourth state the second switch electrically connects the first node to an end of the fourth resistor distal to the other end of the fourth resistor coupled to the third node.

6. The device according to claim 2, wherein
the bridge circuit has one of a first configuration, a second configuration and a third configuration;
in the first configuration another subset of the plurality of resistors of the first resistor and the fourth resistor are light dependent resistors which are each optically illuminated with first synchronized optical signals having the same time dependent variation in illumination;
in the second configuration the second resistor and the third resistor are light dependent resistors which are each optically illuminated with second synchronized optical signals having the same time dependent variation in illumination; and
in the third configuration the another subset of the plurality of resistors of the first resistor and the fourth resistor are light dependent resistors which are each optically illuminated with third synchronized optical signals having the same time dependent variation in illumination and the second resistor and the third resistor are light dependent resistors which are each optically illuminated with synchronized fourth optical signals having the same time dependent variation in illumination.

7. The device according to claim 1, wherein
the first sample-and-hold (SH) circuit is coupled to a first source having an output coupled to a reference arm of a comparator circuit; and
the device further comprises a second SH circuit coupled to a second source having an output coupled to a test arm of a comparator circuit;
the reference arm comprises a reference resistor and a reference winding comprising a fixed number of turns in series between he first SH circuit and ground;
the test arm comprises a resistor and a variable winding comprising a variable number of turns in series between the second SH circuit and ground; and
the comparator circuit supports one or more of voltage reference measurements, current reference measurements and resistor reference measurements.

8. The device according to claim 7, wherein
a first node connected at a junction between the reference resistor and a reference winding is connected to a first port of a measurement circuit;
a second node connected at a junction between the resistor and the variable winding is coupled to a second port of the measurement circuit; and
the measurement circuit comprises one of a null detector and a voltmeter.

9. The device according to claim 7, wherein
the device forms part of one of a direct current comparator bridge and a high resistance bridge.

10. The device according to claim 1, wherein
the first sample-and-hold (SH) circuit is coupled to a first source having an output coupled to a first node of a bridge circuit comprising the first node, a second node, a third node and a fourth node;
the device further comprises:
a second SH circuit coupled to a second source having an output coupled to the fourth node of the bridge circuit;
the bridge circuit comprises:
a first resistor coupled to the first node and the second node;
a second resistor coupled to first node and the third node;
a third resistor coupled to the second node and the fourth node; and
a fourth resistor coupled to the third node and the fourth node;
a first output port coupled to the second node; and
a second output port coupled to the third node;
the first resistor comprises a plurality of resistors in parallel of which a subset of the plurality of resistors are electrically tunable; and
adjustment of the subset of the plurality of resistors provides for adjustment of a voltage divider comprising the first resistor and third resistor.

11. The device according to claim 10, wherein
the bridge circuit has one of a first configuration, a second configuration and a third configuration;
in the first configuration another subset of the plurality of resistors of the first resistor and the fourth resistor are light dependent resistors which are each optically illuminated with first synchronized optical signals having the same time dependent variation in illumination;
in the second configuration the second resistor and the third resistor are light dependent resistors which are each optically illuminated with second synchronized optical signals having the same time dependent variation in illumination; and
in the third configuration the another subset of the plurality of resistors of the first resistor and the fourth resistor are light dependent resistors which are each optically illuminated with third synchronized optical signals having the same time dependent variation in illumination and the second resistor and the third resistor are light dependent resistors which are each optically illuminated with synchronized fourth optical signals having the same time dependent variation in illumination.

12. The device according to claim 10, wherein
a first node connected at a junction between the reference resistor and a reference winding is connected to a first port of a measurement circuit;
a second node connected at a junction between the resistor and the variable winding is coupled to a second port of the measurement circuit; and
the measurement circuit comprises one of a null detector and a voltmeter.

13. The device according to claim 10, wherein
the device forms part of one of a direct current comparator bridge and a high resistance bridge.

14. The device according to claim 1, wherein
the first sample-and-hold (S/H) circuit is coupled to an output of the amplifier by a first switch and to a first arm of a bridge or a null detector;
the device further comprises:
an amplifier;
a second S/H circuit coupled to the output of the amplifier by the first switch and to a second arm of the bridge or null detector; and
a controller connected to the amplifier, the first switch, the first S/H circuit, the second switch and the second S/H circuit; and
the controller executes a process comprising the sequential steps of:
connecting the output of the amplifier to the first S/H circuit and connecting an input of the amplifier to a first source;
setting the first S/H circuit;
connecting the output of the amplifier to the second S/H circuit and connecting an input of the amplifier to a second source;
setting the second S/H circuit; and
connecting within a defined time period the first S/H circuit to the first arm of the bridge or null detector and the second S/H circuit to the second arm of the bridge or null detector.

15. The device according to claim 14, wherein
each of the first source and the second source are either a voltage source or a current source and the amplifier is an electrical amplifier.

16. The device according to claim 14, wherein
each of the first source and the second source are optical sources and the amplifier is an optical amplifier.

17. A method comprising:
employing a system to perform a measurement or self-calibrate one or more electrical standards.

18. The method according to claim 17, wherein
the system executes a process relating to performing the measurement; and
the process comprises:
selectively coupling an amplifier to each of a pair of sample-and-hold (S/H) circuits to generate a pair of signals; and
coupling the pair of signals from the outputs of the pair of S/H circuits to a measurement circuit for performing a measurement; wherein
the outputs of the pair of S/H circuits are coupled to the circuit within a defined time period and each S/H circuit of the pair of S/H circuits is coupled to a defined port of the measurement circuit; and
the measurement circuit comprising a bridge selected from the group comprising a direct current comparator resistance bridge, a Wheatstone bridge, a dual source bridge and a null detector bridge circuit.

19. The method according to claim 18, wherein
the amplifier is one of an electrical amplifier and an optical amplifier.

20. The method according to claim 18, wherein
one of:
the amplifier is an electrical amplifier and the circuit is an electrical null detector; and
the amplifier is an optical amplifier and the circuit is an optical null detector.

21. The method according to claim 17, wherein
the system executes a process relating to self-calibrating one or more electrical standards; and
the process comprises:
providing a network of resistors in series and parallel;
providing a self-calibrating null detector; and
employing the self-calibrating null detector to generate a series of self-calibrated ratios of the resistors within the network of resistors; and
employing the series of self-calibrated ratios to self-calibrate one or more electrical standards selected from the group comprising a resistance standard, a voltage standard and a current standard.
